(19) United States
(12) Patent Application Publication
(10) Pub. No.: US 2013/0082727 A1
(43) Pub. Date: Apr. 4, 2013

(54) WAFER TRAY, SEMICONDUCTOR WAFER TEST APPARATUS, AND TEST METHOD OF SEMICONDUCTOR WAFER

(71) Applicant: Shigeru Matsumura, Kumagayashi (JP)

(72) Inventor: Shigeru Matsumura, Kumagayashi (JP)

(73) Assignee: ADVANTEST CORPORATION, Tokyo (JP)

(21) Appl. No.: 13/704,290

(22) PCT Filed: Aug. 31, 2010
(86) PCT No.: PCT/JP2010/064830

§ 371 Date: Dec. 14, 2012

(51) Int. Cl. H01L 21/683; G01R 1/04

(52) U.S. Cl. CPC H01L 21/683; G01R 1/0408
USPC 324/750.16; 269/58

(57) ABSTRACT

A wafer tray which holds a semiconductor wafer includes a wafer set plate on which the semiconductor wafer is set, a tray body which supports the wafer set plate to be able to finely move, and a vibration actuator which imparts vibration to the wafer set plate.

### TECHNICAL FIELD

The present invention relates to a wafer tray which holds a semiconductor wafer on which integrated circuit devices and other devices under test (hereinafter also referred to representatively as “IC devices”) are formed, a semiconductor wafer test apparatus for testing IC devices which are formed on a semiconductor wafer, and a test method of a semiconductor wafer.

### BACKGROUND ART

As a semiconductor wafer test apparatus which is used for testing IC devices in a wafer state, one is known which forms a sealed space between a probe and a wafer tray and reduces the pressure of that sealed space so as to make bumps of the probe and electrodes of the IC devices electrically contact each other (see, for example, PLT 1).

### CITATIONS LIST

### Patent Literature

PLT 1: Japanese Patent Publication No. 2009-203943 A1

### SUMMARY OF INVENTION

### Technical Problem

Electrodes of IC devices of a semiconductor wafer are formed with an Al₂O₃ or other oxide film on them, so to enable reliable connection of the bumps and electrodes, this oxide film has to be broken.

The technical problem of the present invention is to provide a wafer tray, semiconductor wafer test apparatus, and test method of a semiconductor wafer which can stabilize the electrical connection between a probe and devices under test.

### Solution to Problem

(1) The wafer tray according to the present invention is a wafer tray which holds a semiconductor wafer, the wafer tray characterized by comprising: a set part on which the semiconductor wafer is set; a main body which supports the set part to be able to finely move; and a vibration imparting means which imparts vibration to the set part (see claim 1).

In the above invention, preferably the vibration imparting means is interposed between the set part and the main body (see claim 2).

In the above invention, preferably the vibration imparting means includes a piezoelectric ceramic actuator (see claim 3).

In the above invention, the wafer tray may also comprise rolling elements are interposed between the set part and the main body (see claim 4).

The semiconductor wafer test apparatus according to the present invention is characterized by comprising: the above wafer tray; a moving means which moves the wafer tray relative to a probe which is to be electrically connected to devices under test which are formed on the semiconductor wafer; and a pressure reducing means which reduces a pressure of a sealed space which is formed between the probe and the wafer tray (see claim 5).

In the above invention, the semiconductor wafer test apparatus may further comprise a positioning means which positions the semiconductor wafer relative to the probe.

The test method of a semiconductor wafer according to the present invention is a test method using the above semiconductor wafer test apparatus characterized by comprising: a moving step of using the moving means to move the wafer tray so as to form a sealed space between the probe and the wafer tray; a first pressure reducing step of using the pressure reducing means to reduce a pressure of the sealed space to a first pressure; a vibration imparting step of using the vibration imparting means to vibrate the wafer tray in a state where electrodes of the semiconductor wafer and contactors of the probe contact; and a second pressure reducing step of using the pressure reducing means to reduce a pressure of the sealed space to a second pressure which is lower than the first pressure (see claim 6).

In the above invention, the test method may further comprise a positioning step of using the positioning means to position the semiconductor wafer relative to the probe.

(2) A semiconductor wafer test apparatus according to the present invention is characterized by comprising: a wafer tray which holds a semiconductor wafer; a moving means which moves the wafer tray relative to a probe which is to be electrically connected to devices under test which are formed on the semiconductor wafer; a pressure reducing means which reduces a pressure of a sealed space which is formed between the probe and the wafer tray; and a vibration imparting means which imparts vibration to the wafer tray (see claim 7).

A test method of a semiconductor wafer according to the present invention is a test method using the semiconductor wafer test apparatus characterized by comprising: a moving step of using the moving means to move the wafer tray relative to the probe so that electrodes of the semiconductor wafer and contactors of the probe contact; a vibration imparting step of using the vibration imparting means to vibrate the wafer tray in a state where the electrodes and the contactors contact; and a pressure reducing step of using the pressure reducing means to reduce a pressure of the sealed space (see claim 8).

A test method of a semiconductor wafer according to the present invention is a test method using the above semiconductor wafer test apparatus characterized by comprising: a first moving step of using the moving means to move the wafer tray so as to form a scaled space between, the probe and the wafer tray; a first pressure reducing step of using the pressure reducing means to reduce a pressure of the sealed space to a first pressure; a second moving step of moving the moving means so that the moving means again contacts the wafer tray; a vibration imparting step of using the vibration imparting means to vibrate the wafer tray in a state where electrodes of the semiconductor wafer and contactors of the probe contact; and a second pressure reducing step of using the pressure reducing means to reduce a pressure of the sealed space to a second pressure which is lower than the first pressure (see claim 9).

A test method of a semiconductor wafer according to the present invention is a test method using the above semiconductor wafer test apparatus characterized by comprising: a moving step of using the moving means to move the wafer tray so as to form a sealed space between the probe and the wafer tray; a first pressure reducing step of using the pressure reducing means to reduce a pressure of the sealed space to a first pressure; a vibration imparting step of using the vibration imparting means to vibrate the wafer tray in a state where electrodes of the semiconductor wafer and contactors of the probe contact; and a second pressure reducing step of using the pressure reducing means to reduce a pressure of the sealed space to a second pressure which is lower than the first pressure (see claim 10).

In the above invention, the test method may further comprise a positioning step of using the positioning means to position the semiconductor wafer relative to the probe.

### Advantageous Effects of Invention

In the present invention, it is possible to vibrate a semiconductor wafer relative to a probe through a wafer tray so as to break the oxide film which is formed on electrodes of the semiconductor wafer and possible to stabilize the electrical connection between devices under test and the probe.

### BRIEF DESCRIPTION OF DRAWINGS

FIG. 1 is a schematic side view which shows a semiconductor wafer test apparatus in a first embodiment of the present invention.

FIG. 2 is a plan view which shows a wafer tray in the first embodiment of the present invention.

FIG. 3 is a cross-sectional view along a line III-III of FIG. 2.

FIG. 4 is a plan view which shows a holding stage of a movement apparatus in the first embodiment of the present invention.

FIG. 5 is a cross-sectional view along a line V-V of FIG. 4.

FIG. 6 is a flow chart of a test method of a semiconductor wafer in the first embodiment of the present invention.

FIG. 7A is a view which shows a step S11 of FIG. 6.

FIG. 7B is a view which shows a step S12 of FIG. 6.

FIG. 7C is a view which shows a step S13 of FIG. 6.

FIG. 7D is an enlarged cross-sectional view of a part VII of FIG. 7C.

FIG. 8 is a flow chart of a test method of a semiconductor wafer in a second embodiment of the present invention.

FIG. 9A is a view which shows a step S21 of FIG. 8.

FIG. 9B is a view which shows a step S22 of FIG. 8.

FIG. 9C is a view which shows a step S23 of FIG. 8.

FIG. 9D is a view which shows a step S24 of FIG. 8.

FIG. 9E is a view which shows a step S25 of FIG. 8.

FIG. 10 FIG. 10 is a cross-sectional view of a wafer tray in a third embodiment of the present invention.

FIG. 11 is a flow chart of a test method of a semiconductor wafer in the third embodiment of the present invention.

FIG. 12A is a view which shows a step S31 of FIG. 11.

FIG. 12B is a view which shows a step S32 of FIG. 11.

FIG. 12C is a view which shows a step S33 of FIG. 11.

FIG. 12D is a view which shows a step S34 of FIG. 11.

### DESCRIPTION OF EMBODIMENTS

Below, a first embodiment of the present invention will be explained based on the drawings.

### First Embodiment

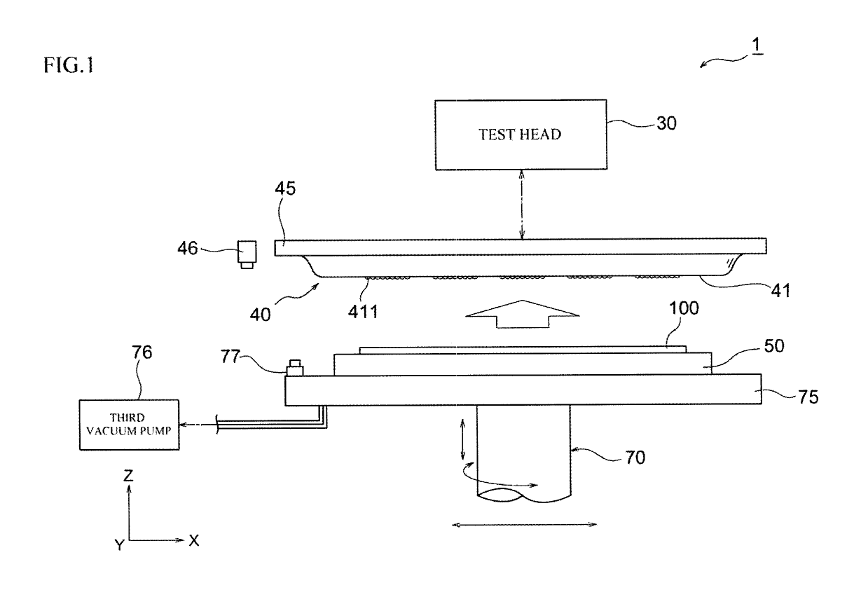

FIG. 1 is a view which shows a semiconductor wafer test apparatus in the present embodiment.

The semiconductor wafer test apparatus 1 in the present embodiment (electronic device test apparatus) is an apparatus which tests electrical properties of IC devices which are formed on a semiconductor wafer 100. As shown in FIG. 1, it comprises a test head 30, a probe 40 (a probe card), a wafer tray 50, and a movement apparatus 70. Note that, the semiconductor wafer test apparatus which is explained below is just one example. The present invention is not particularly limited to this.

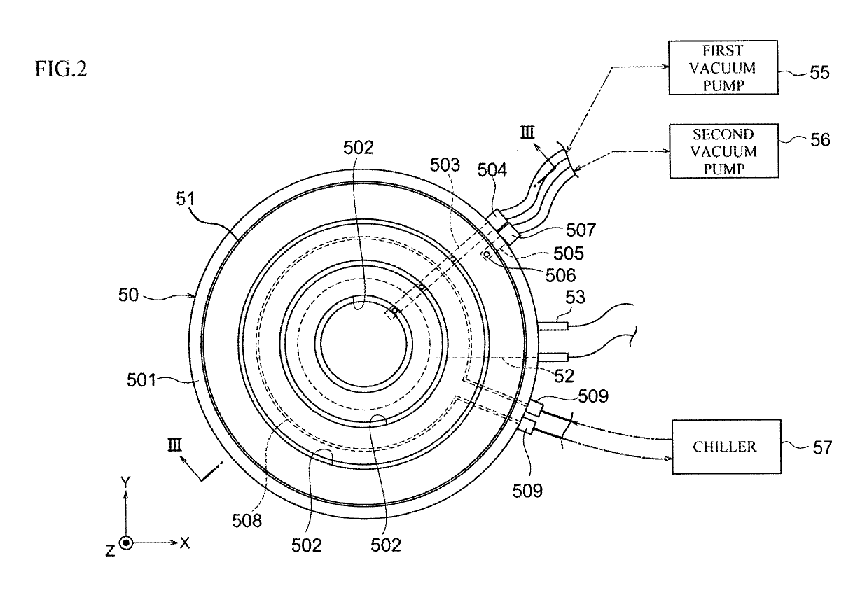

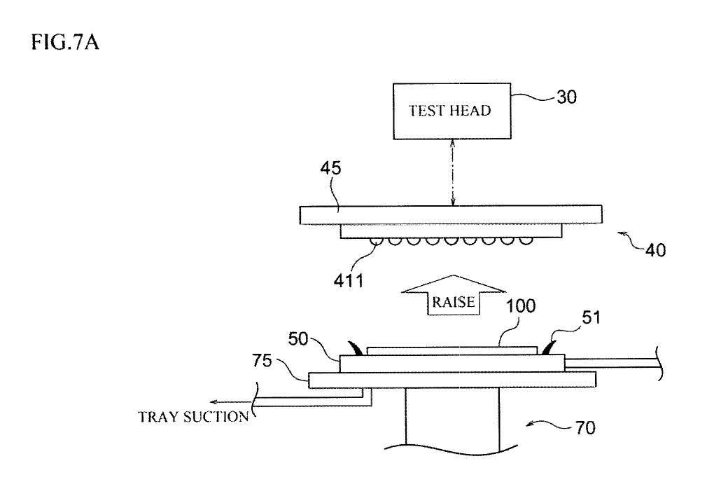

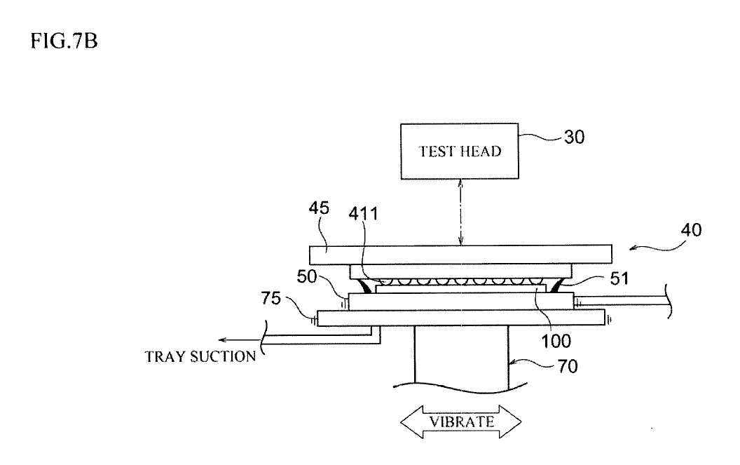

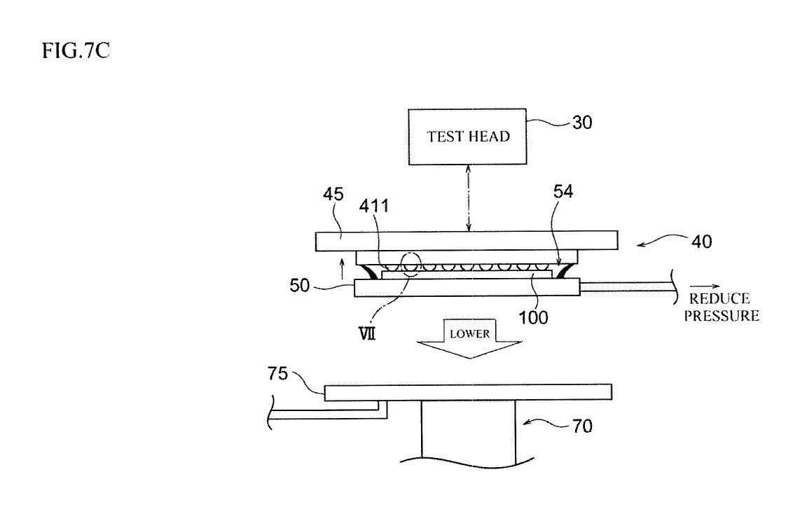

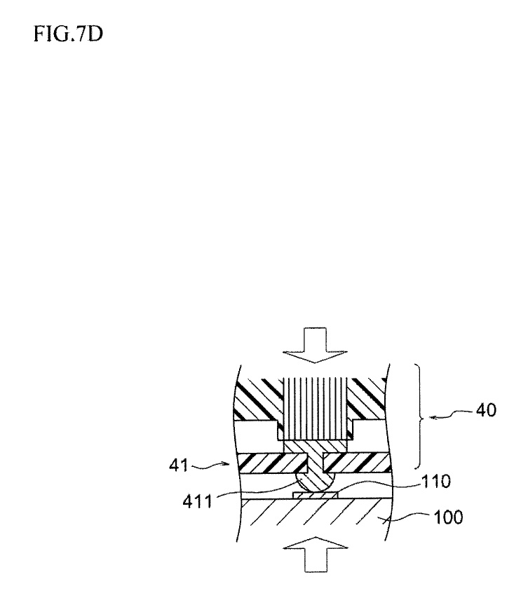

In this semiconductor wafer test apparatus 1, at the time of testing IC devices, a semiconductor wafer 100 which is held on the wafer tray 50 is made to face the probe 40 by the movement apparatus 70. In this state, a second vacuum pump 56 (see FIG. 2) is used to reduce the pressure inside of the sealed space 54 (see FIG. 7C) whereby the semiconductor wafer 100 is pushed against the probe 40. Furthermore, in this state, test signals are input from the test head 30 to the IC device and output back whereby the IC devices are tested. Note that, a system other than pressure reduction (for example a pressing system) may also be used to push the semiconductor wafer 100 against the probe 40.

The probe 40 comprises a membrane 41 which has a large number of bumps 411 which are to electrically contact electrodes 110 of the semiconductor wafer 100 (see FIG. 7D), and the membrane 41 is electrically connected through a not particularly shown anisotropic conductive rubber sheet or pitch changing board to a performance board 45. The performance board 45 is electrically connected to pin electronics which are contained in the test head 30 through not particularly shown connectors, cables, etc.

Note that, the structure of the probe is not particularly limited to the above one. Further, as contactors, instead of the above membrane 41, cantilever type probe pins or pogo pins etc. may be used.

Further, a first camera 46 which captures an image of the electrodes 110 of the semiconductor wafer 100 is, for example, provided on a top plate (not shown) of a prober. An image processing system (not shown) detects the positions of the electrodes 110 of the semiconductor wafer 100 from the image which is captured by the first camera 46. Further, the movement apparatus 70 positions the semiconductor wafer 100 relative to the probe 40 on the basis of the positional information of the electrodes 110 and the positional information of the bumps 411 of the probe 40 which are detected by using a later explained second camera 77. Note that, the first camera 46 and the later explained movement apparatus 70 and second camera 77 in the present embodiment are equivalent to one example of the positioning means in the present invention.

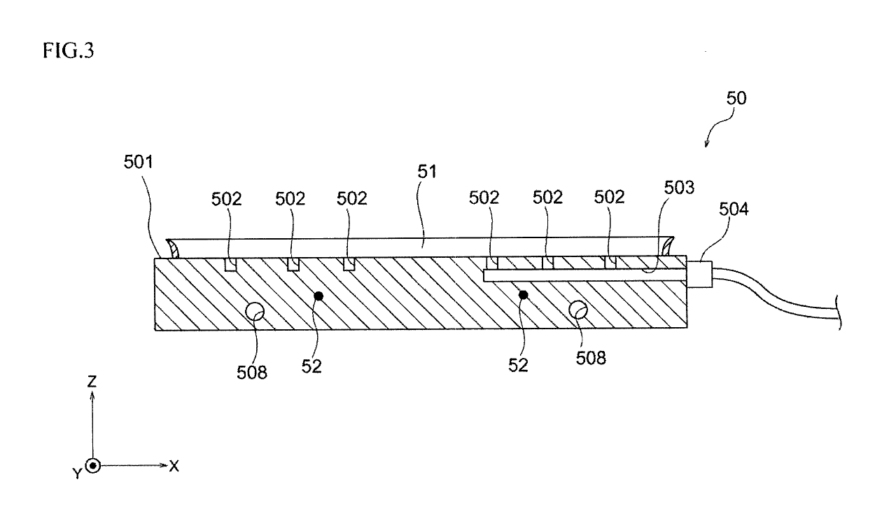

FIG. 2 and FIG. 3 are views which show a wafer tray in the present embodiment.

The wafer tray 50 (wafer holding device), as shown in FIG. 2 and FIG. 3, is a disk-shaped member which has a flat top surface 501 and which has a diameter which is larger than a semiconductor wafer 100.

The top surface 501 of this wafer tray 50 is formed with three ring-shaped grooves 502 of diameters smaller than the semiconductor wafer 100 in a concentric manner. These ring-shaped grooves 502 are communicated with a suction passage 503 which is formed inside of the wafer tray 50. This suction passage 503 is connected through a suction port 504 to a first vacuum pump 55.

Therefore, when using the first vacuum pump 55 to apply suction in the state where a semiconductor wafer 100 is set on the wafer tray 50, the negative pressure which is formed inside of the ring-shaped grooves 502 is used to hold the semiconductor wafer 100 by suction on the wafer tray 50. Note that, the shape and number of the ring-shaped grooves 502 are not particularly limited.

Further, a pressure reduction-use passage 505 is formed inside of the wafer tray 50. This pressure reduction-use passage 505 opens at a suction hole 506 which is positioned on the top surface 501 at the outside from the ring-shaped grooves 502. This pressure reduction-use passage 505 is connected through a pressure reduction port 507 to a second vacuum pump 56.

Further, a ring-shaped seal member 51 is provided near the outer circumference of the top surface 501 of the wafer tray 50. As specific examples of this seal member 51, for example, a packing which is composed of silicone rubber etc. may be illustrated. When the wafer tray 50 is pushed against the probe 40, this seal member 51 forms the sealed space 54 between the top surface 501 of the wafer tray 50 and the probe 40 (see FIG. 7C).

Furthermore, a heater 52 is embedded inside of the wafer tray 50 for heating the semiconductor wafer 100. Further, a coolant passage 508 is formed inside this wafer tray 50 for circulating a coolant. This coolant passage 508 is connected through a pair of cooling ports 509 to a chiller 57.

Note that, instead of the heater 52, a heat medium may also be circulated through a passage which is formed in the wafer tray 50 so as to heat the semiconductor wafer 100. Further, when just heating the semiconductor wafer 100, it is sufficient to just embed the heater 52 inside the wafer tray 50. On the other hand, when just cooling the semiconductor wafer 100, it is sufficient to form just a cooling passage 508 in the wafer tray 50.

Further, the wafer tray 50 has a temperature sensor 53 embedded in it to measure the temperature of the semiconductor wafer 100. The above-mentioned heater 52 or chiller 57 adjusts the temperature of the wafer tray 50 on the basis of the results of measurement of the temperature sensor 53 whereby the temperature of the semiconductor wafer 100 is maintained at the target temperature.

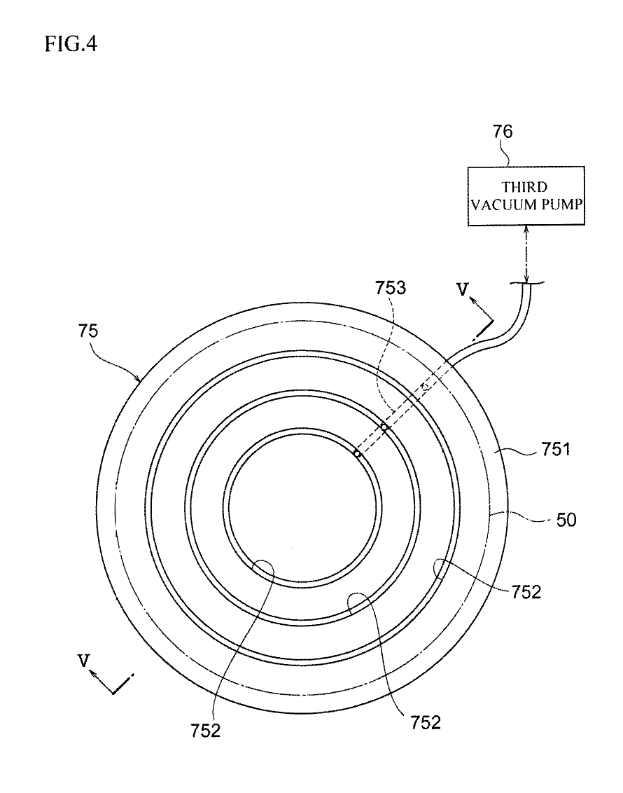

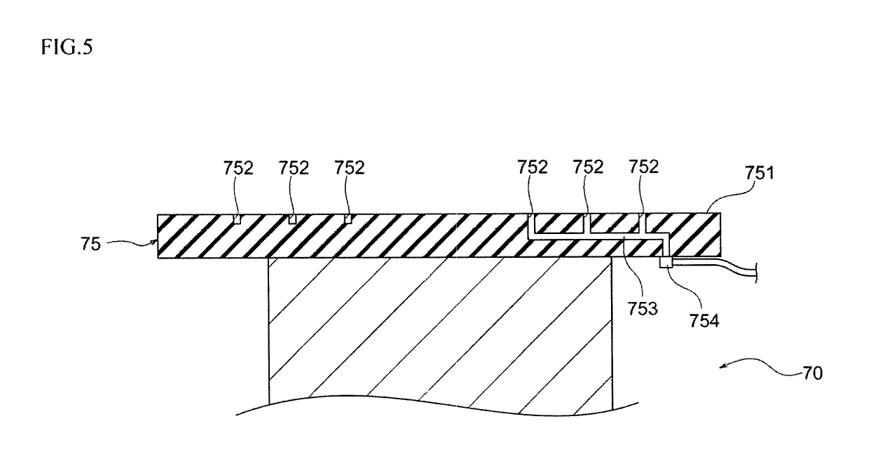

FIG. 4 and FIG. 5 are views which show a holding stage of the movement apparatus in the present embodiment.

The movement apparatus 70 in the present embodiment, as shown in FIG. 1, has a holding stage 75 which is able to hold the above-mentioned wafer tray 50.

The holding stage 75, as shown in FIG. 4 and FIG. 5, is a disk-shaped member which has a flat top surface 751 and which has a diameter which is larger than the wafer tray 50.

The top surface 751 of this holding stage 75 is formed with three ring-shaped grooves 752 of radii smaller than the wafer tray 50 in a concentric manner. These ring-shaped grooves 752 are communicated with a suction passage 753 which is formed inside the holding stage 75. Furthermore, this suction passage 753 is connected through a suction port 754 to a third vacuum pump 76.

Therefore, when using this third vacuum pump 76 to apply suction in the state where a wafer tray 50 is set on this holding stage 75, the negative pressure which is formed inside of the ring-shaped grooves 752 is used to hold the wafer tray 50 by suction on the holding stage 75. Note that, the shape and number of ring-shaped grooves 752 are not particularly limited.

Further, this movement apparatus 70, as shown in FIG. 1, can use a motor or ball screw mechanism etc. to move the holding stage 75 in three dimensions (X-Y-Z directions) and to rotate it about the Z-axis in FIG. 1. In particular, in the present embodiment, this movement apparatus 60 can move back and forth by a predetermined frequency (vibrate) along the XY-plane (direction substantially parallel to top surface 501 of the wafer tray 50). The stroke of this back and forth motion, for example, is preferably ±20 [μm] or less, particularly preferably ±10 [μm] or less, but is not particularly limited. Note that, the movement apparatus 70 in the present embodiment is equivalent to one example of the moving means and vibration imparting means in the present invention.

Further, this holding stage 75 is provided with a second camera 77 which captures an image of bumps 411 of the probe 40. An image processing system (not shown) detects the positions of the bumps 411 of the probe 40 from the image which is captured by this second camera 77. Further, as explained above, the movement apparatus 70 positions the semiconductor wafer 100 relative to the probe 40 on the basis of the positional information of the bumps 411 and the positional information of the electrodes 110 of the semiconductor wafer 100. Note that, FIG. 4 and FIG. 5 do not show the second camera 77.

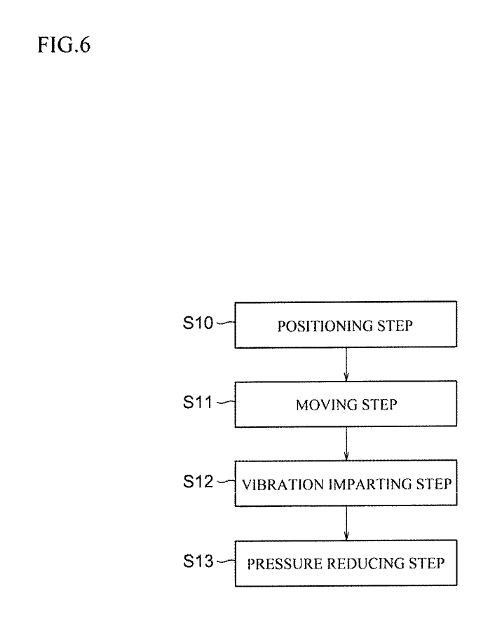

Next, the test method of a semiconductor wafer 100 using the semiconductor wafer test apparatus 1 which is explained above will be explained with reference to FIG. 6 to FIG. 7D.

FIG. 6 is a flow chart of a test method of a semiconductor wafer in the present embodiment, while FIG. 7A to FIG. 7D are views which show steps of FIG. 6.

When a semiconductor wafer 100 is placed on the wafer tray 50, the first vacuum pump 55 generates a negative pressure inside of the ring-shaped grooves 502 whereby the semiconductor wafer 100 is held by suction on the wafer tray 50.

Next, using the first and second cameras 46 and 77, the movement apparatus 70 positions the semiconductor wafer 100 with respect to the probe 40 (step S10 of FIG. 6). Then, in step S11 of FIG. 6, as shown in FIG. 7A, the movement apparatus 70 moves the holding stage 75 upward until a position where the electrodes 110 of the semiconductor wafer 100 and the bumps 411 of the probe 40 contact. In this state, the electrodes 110 of the semiconductor wafer 100 and the bumps 411 of the probe 40 lightly contact by, for example, a weak force of 0.1 to 2 [gf/pin] (=0.98×10⁻³ to 19.6×10⁻³ [N/pin]) or so. Note that, the unit [gf/pin] shows the force which is applied per one electrode 110 of the semiconductor wafer 100.

Next, in step S12 of FIG. 6, as shown in FIG. 7B, the movement apparatus 70 moves back and forth by a predetermined frequency along the XY-plane (direction substantially parallel to the top surface 501 of the wafer tray 50) so as to finely vibrate the semiconductor wafer 100 with respect to the probe 40. Due to this, the electrodes 110 of the semiconductor wafer 100 is scrubbed by the bumps 411 of the probe 40 whereby the oxide film which is formed on the surface of the electrodes 110 is broken and stable electrical connection between the probe 40 and the IC devices of the semiconductor wafer 100 can be secured.

Next, in step S13 of FIG. 6, as shown in FIG. 7C, the second vacuum pump 56 operates to reduce the pressure inside of the sealed space 54 through the pressure reduction-use passage 505. Due to this pressure reduction, the wafer tray 50 is pulled toward the probe 40 and, as shown in FIG. 7D, for example, the electrodes 110 of the semiconductor wafer 100 are pushed against the bumps 411 of the probe 40 by a strong force of 5 to 10 odd [gf/pin] (=49.0×10⁻³ to 200.0×10⁻³ [N/pin]) or so, so the electrodes 110 and bumps 411 completely connect with each other.

In this state, test signals are input from the test head 30 through the probe 40 to the IC devices of the semiconductor wafer 100 and output back so as to test the IC devices.

Note that, before reducing of the pressure of the sealed space 54 by the second vacuum pump 56 or substantially simultaneously with it, the third vacuum pump 76 stops to release the suction on the wafer tray 50 by the holding stage 75.

In the above way, in the present embodiment, a semiconductor wafer 100 is finely vibrated relative to the probe 40 through the wafer tray 50, so the oxide film which is formed on the electrodes 110 of the semiconductor wafer 100 can be broken and stable electrical connection between the IC devices of the semiconductor wafer 100 and probe 40 can be secured.

Further, in a pushing type prober, a rigidity able to withstand an extremely large load (several hundred [kg] or 1 [ton] or so) at the time of contact of a semiconductor wafer and probe is demanded from the stage. For this reason, when vibrating this stage, the vibration imparting mechanism also becomes larger in size and higher in cost. As opposed to this, in the present embodiment, the holding stage 75 is only required to have a rigidity of an extent enough to make the semiconductor wafer and probe lightly contact, so it is possible to simplify the configuration of the vibration imparting mechanism.

### Second Embodiment

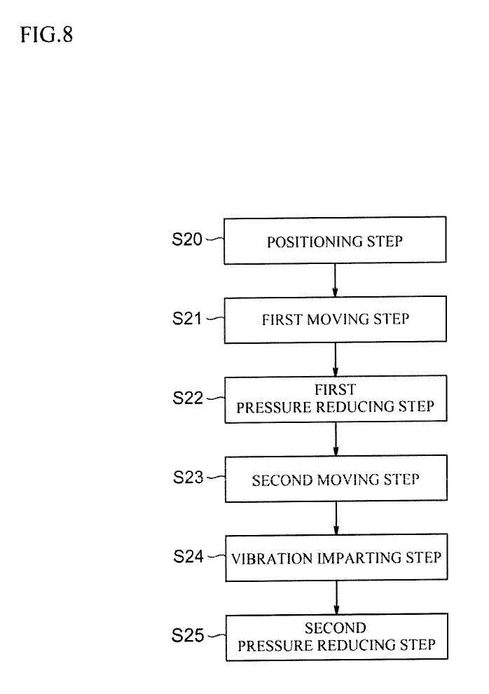

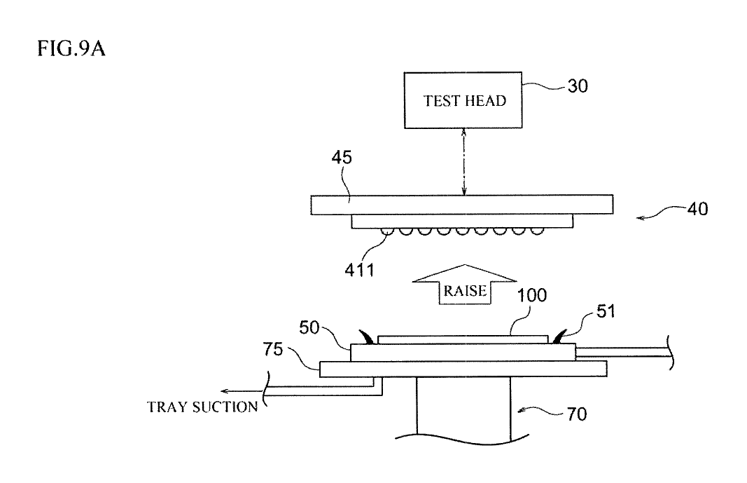

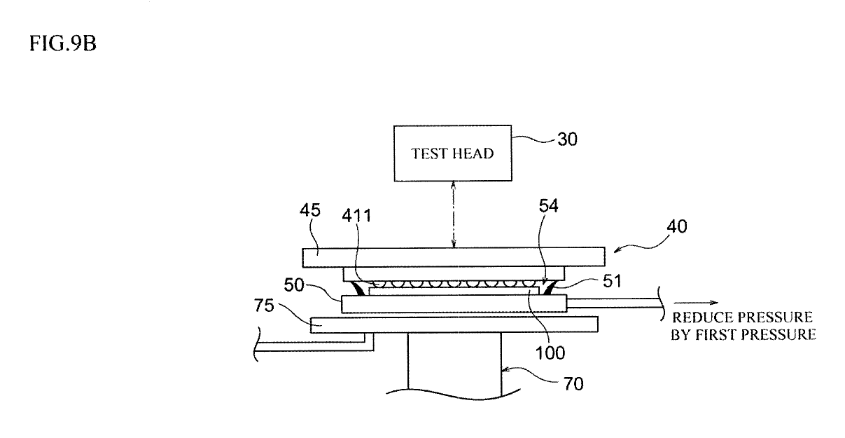

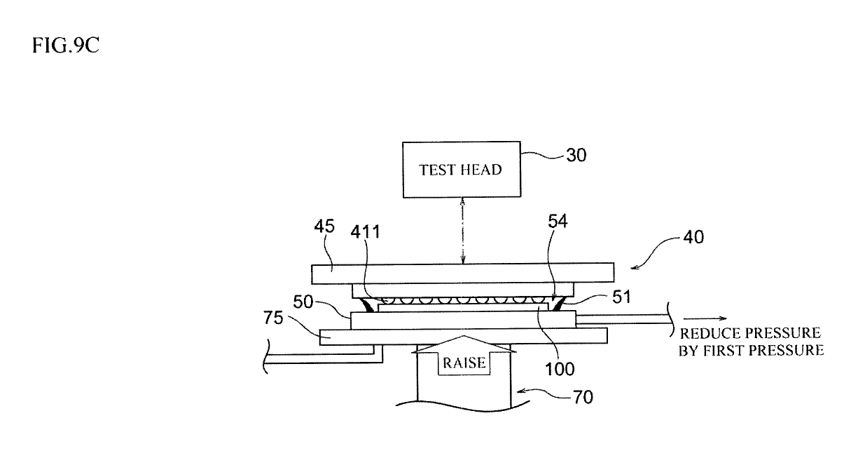

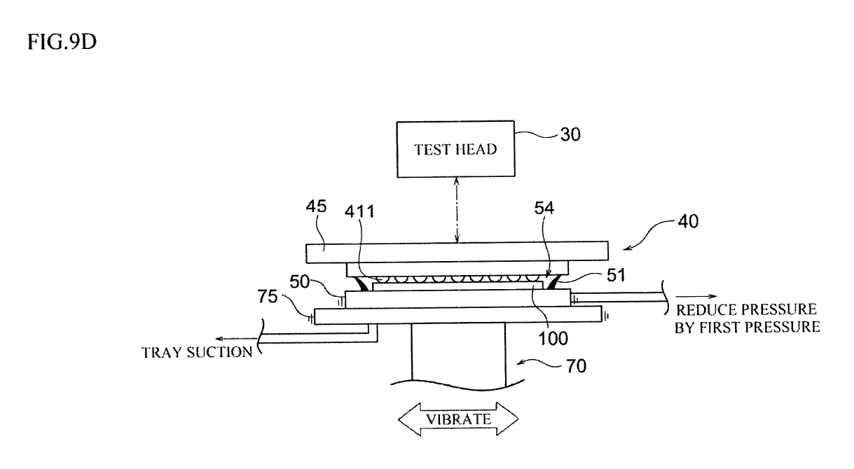

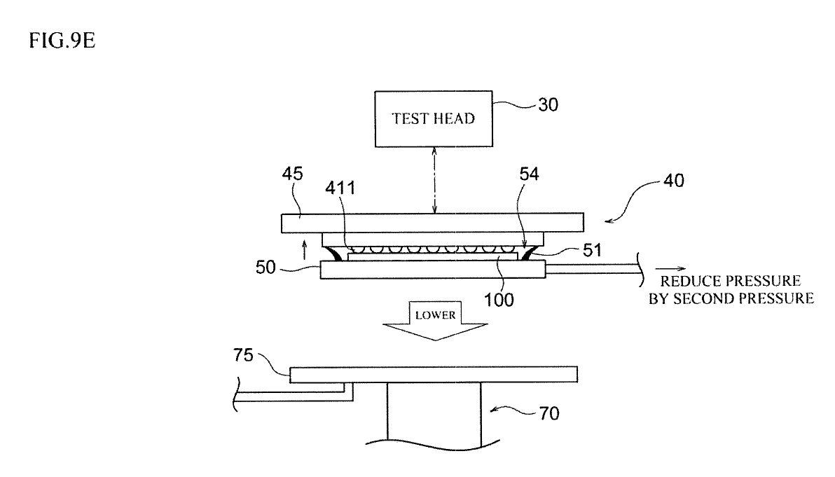

In this embodiment of the present invention, the mechanical configuration of the semiconductor wafer test apparatus is the same as that of the above first embodiment. The method of testing the semiconductor wafer differs from the first embodiment. Therefore, the semiconductor wafer test apparatus is assigned the same reference numerals and explanations are omitted. Below, while referring to FIG. 8 to FIG. 9E, a test method of a semiconductor wafer in the present embodiment will be explained.

FIG. 8 is a flow chart of a test method of a semiconductor wafer in the present embodiment, while FIG. 9A to FIG. 9E are views which show steps of FIG. 8.

In the same way as the first embodiment, when a semiconductor wafer 100 is placed on the wafer tray 50, the first vacuum pump 55 operates to hold the semiconductor wafer 100 by suction on the wafer tray 50.

Next, using the first and second cameras 46 and 77, the movement apparatus 70 positions the semiconductor wafer 100 with respect to the probe 40 (step S20 of FIG. 8). Then, in step S21 of FIG. 8, as shown in FIG. 9A, the movement apparatus 70 moves the holding stage 75 upward until a position where the wafer tray 50 can stick to the probe 40 by suction.

Next, in step S22 of FIG. 8, as shown in FIG. 9B, the third vacuum pump 76 stops to release the suction hold of the wafer tray 50 by the holding stage 75 and the second vacuum pump 56 operates to reduce the pressure inside of the sealed space 54 to the first pressure P₁. This first pressure P₁ is a pressure of an extent whereby the electrodes 110 of the semiconductor wafer 100 and the bumps 411 of the probe 40 contact by a weak force of, for example, 0.1 to 2 [gf/pin] (=0.98×10⁻³ to 19.6×10⁻³ [N/pin]) or so and a pressure of a low relative vacuum degree.

Due to the pressure reduction in step S22, the wafer tray 50 is pulled to the probe 40, so a clearance is formed between the wafer tray 50 and the holding stage 75. For this reason, in step S23 of FIG. 8, as shown in FIG. 9C, the movement apparatus 70 uses torque control to move the holding stage 75 upward until the holding stage 75 contacts the wafer tray 50. When the holding stage 75 contacts the wafer tray 50, the third vacuum pump 76 operates and the holding stage 75 is used to again hold the wafer tray 50 by suction.

Next, in step S24 of FIG. 8, as shown in FIG. 9D, the movement apparatus 70 moves back and forth by a predetermined frequency along the XY-plane (direction substantially parallel to top surface 501 of the wafer tray 50) to finely vibrate the semiconductor wafer 100 with respect to the probe 40. Due to this, the electrodes 110 of the semiconductor wafer 100 are scrubbed by the bumps 411 of the probe 40 whereby the oxide film which is formed on the surface of the electrodes 110 is broken, so stable electrical connection between the probe 40 and the IC devices on the semiconductor wafer 100 can be secured.

Next, in step S25 of FIG. 8, as shown in FIG. 9E, the third vacuum pump 76 stops to release the suction on the wafer tray 50 by the holding stage 75, and the second vacuum pump 56 is used to reduce the pressure inside of the sealed space 54 to the second pressure P₂. This second pressure P₂ is a pressure which is lower relative to the above first pressure P₁ (P₂<P₁) and a pressure which is high in relative vacuum degree.

Due to this pressure reduction, the wafer tray 50 is pulled toward the probe 40 and the electrodes 110 of the semiconductor wafer 100 are pushed against the bumps 411 of the probe 40 by a strong force of for example 5 to 10 odd [gf/pin] (=49.0×10⁻³ to 200.0×10⁻³ [N/pin]) or so, so the electrodes 110 and the bumps 411 are completely connected. In this state, test signals are input from the test head 30 through the probe 40 to the IC devices of the semiconductor wafer 100 and output back so as to test the IC devices.

As explained above, in the present embodiment, the semiconductor wafer 100 is finely vibrated relative to the probe 40 through the wafer tray 50, so the oxide film which is formed on the electrodes 110 of the semiconductor wafer 100 can be broken and stable electrical connection between the IC devices of the semiconductor wafer 100 and the probe 40 can be secured.

Further, in a pushing type prober, a rigidity able to withstand an extremely large load (several hundred [kg] or 1 [ton] or so) at the time of contact of a semiconductor wafer and probe is demanded from the stage. For this reason, when vibrating this stage, the vibration imparting mechanism also becomes larger in size and higher in cost. As opposed to this, in the present embodiment, the holding stage 75 is only required to have a rigidity of an extent which holds the wafer tray, so it is possible to simplify the configuration of the vibration imparting mechanism.

### Third Embodiment

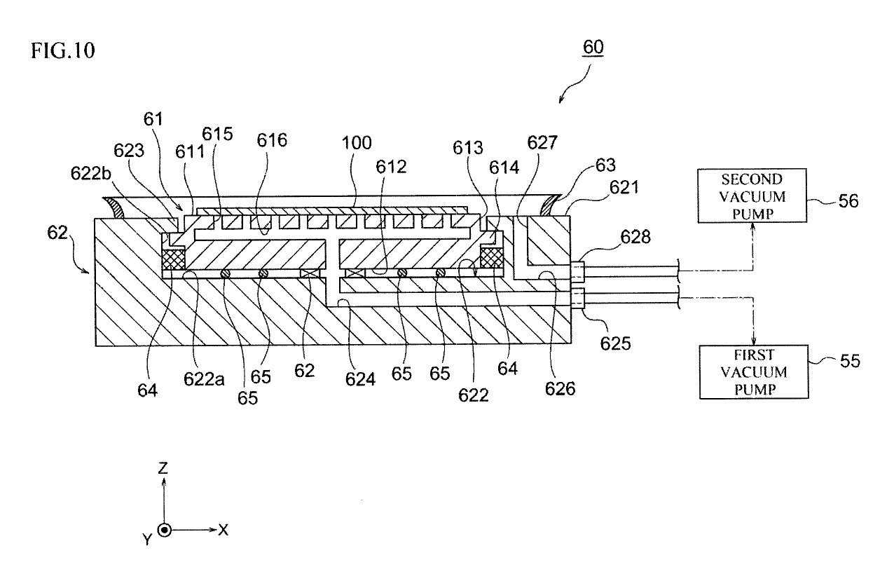

FIG. 10 is a cross-sectional view of a wafer tray in the present embodiment. In the present embodiment, the configuration of the wafer tray 60 differs from the first embodiment, but the rest of the configuration is similar to the first embodiment. Below, only the points of difference of the semiconductor wafer test apparatus in third embodiment from the first embodiment will be explained. Parts configured in the same way as the first embodiment will be assigned the same reference numerals and explanation will be omitted.

The wafer tray 60 in the present embodiment, as shown in FIG. 10, comprises a wafer set plate 61 and a tray body 62. Note that, the wafer set plate 61 in the present embodiment is equivalent to one example of a set part in the present invention, while the tray body 62 in the present embodiment is equivalent to one example of the main body in the present invention.

The wafer set plate 61 has a flat top surface 611 which has a diameter which is larger than a semiconductor wafer 100 and has a flange 614 which sticks out toward the radial direction at its outer circumferential surface 613. The top surface 611 of this wafer set plate 61 is formed with a plurality of the ring-shaped grooves 615 of diameters smaller than the semiconductor wafer 100 in a concentric manner. These ring-shaped grooves 615 are communicated with a suction passage 616 which is formed inside of the wafer set plate 61. Note that, the shape and the number of ring-shaped grooves 615 are not particularly limited.

On the other hand, the tray body 62 has a recessed holding part 622 which holds the wafer set plate 61. A projecting part 623 which sticks out toward the inside is provided at the opening edge of this holding part 622. This projecting part 223 engages with the flange 614 of the wafer set plate 61 which is held inside the holding part 622.

A suction passage 624 is formed inside of the tray body 62 as well. Further, for example, a ring-shaped packing or other first seal member 62 is interposed between the bottom surface 612 of the wafer set plate 61 and the bottom surface 622a of the holding part 622 of the tray body 62. Due to this first seal member 62, the suction passage 616 of the wafer set plate 61 and the suction passage 624 of the tray body 62 are communicated in a state maintaining air-tightness.

Furthermore, the suction passage 624 of the tray body 62 is connected through a suction port 625 to the first vacuum pump 55. Therefore, when using the first vacuum pump 55 to apply suction in the state where a semiconductor wafer 100 is set on the wafer set plate 61, negative pressure is formed inside the ring-shaped grooves 615 through the suction passages 616, 624. Due to this, the semiconductor wafer 100 is held by suction on the wafer tray 60.

Further, a pressure reduction-use passage 626 is formed inside of the tray body 62. This pressure reduction-use passage 626 opens to the top surface 621 at a suction hole 627. This pressure reduction-use passage 626 is connected through a pressure reduction port 628 to the second vacuum pump 56.

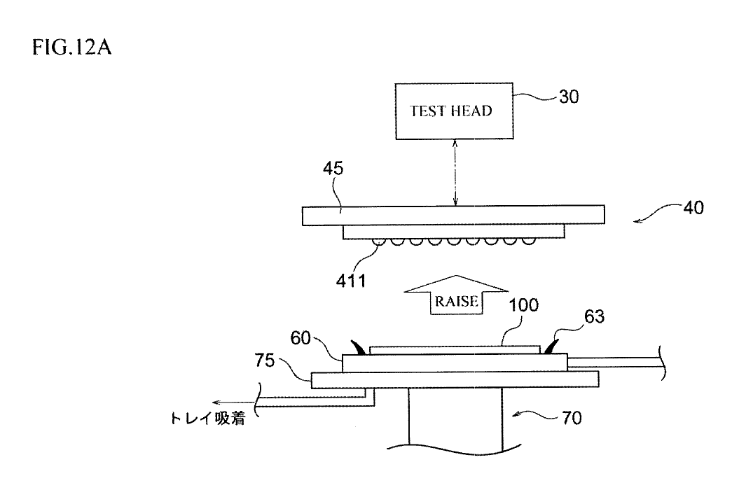

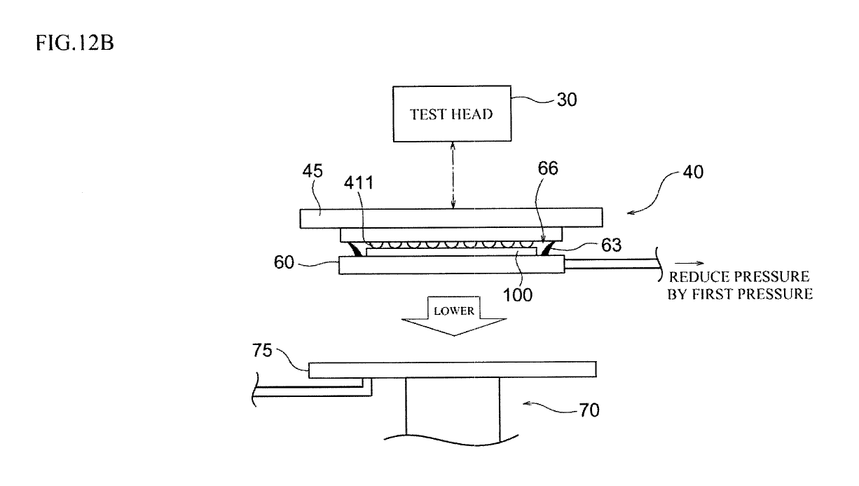

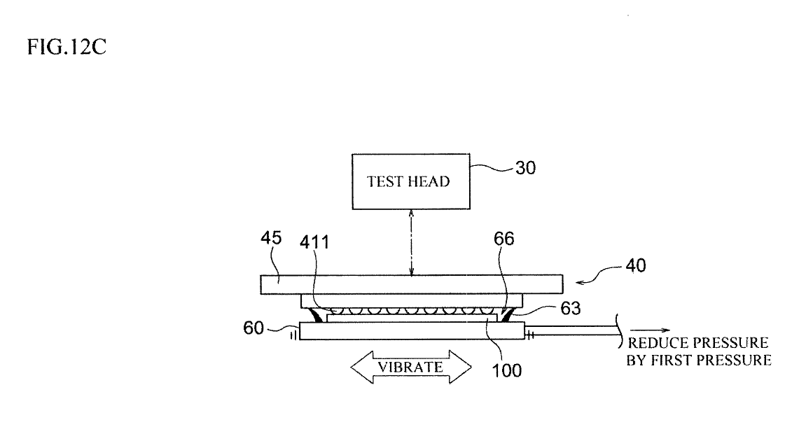

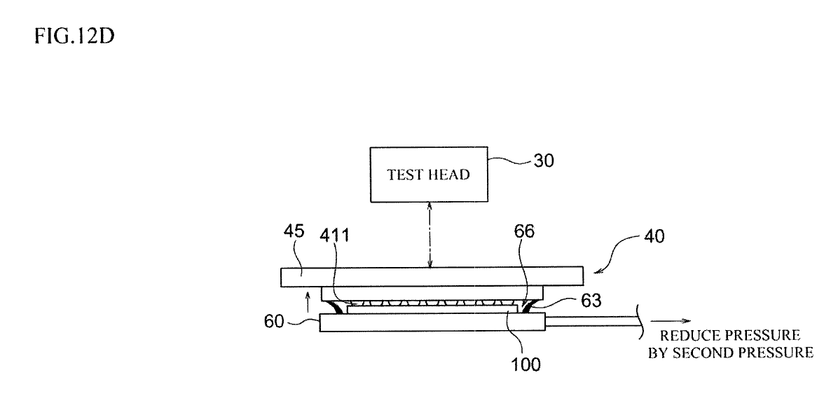

Further, a ring-shaped second seal member 63 is provided near the outer circumference of the top surface 621 of the tray body 62. As a specific example of the second seal member 63, for example, a ring-shaped packing composed of silicone rubber etc. may be illustrated. When a wafer tray 60 is pushed against the probe 40, this second seal member 63 is used to form a sealed space 66 between the wafer tray 60 and the probe 40 (see FIG. 12B to FIG. 12D).

Further, a plurality of vibration actuators 64 are interposed between the outer circumferential 613 of the wafer set plate 61 and the inner circumferential surface 622b of the holding part 622 of the tray body 62. This vibration actuator 64 generates vibration along the XY-plane (direction substantially parallel to the top surface 611 of the wafer carrying plate 61). Note that, in the present embodiment, this vibration actuator 64 is equivalent to one example of the vibration imparting means in the present invention, while the movement apparatus 70 is equivalent to one example of the moving means in the present invention.

As specific example of this vibration actuator 64, for example, it is possible to illustrate a piezoelectric ceramic actuator etc. which expands or contracts and changes in volume due to piezoelectric stain due to application of voltage. The piezoelectric ceramic actuator is a sturdy structure and can give a precise stroke and large thrust, so is suitable for a vibration actuator 64 in the present embodiment.

As the stroke of the vibration which this vibration actuator 64 generates, for example, ±20 [μm] or less is preferable, while ±10 [μm] or less is particularly preferable. Note that, the position of provision of the vibration actuator 64 is not particularly limited. For example, it may also be placed at two locations at the left and right of the wafer set plate 61 or may also be placed at the four sides of the wafer set plate 61.

Further, a plurality of rolling elements 65 are interposed between the bottom surface 612 of the wafer set plate 61 and the bottom surface 622a of the holder 622 of the tray body 62. The rolling elements 65 allow relative movement of the wafer set plate 61 with respect to the tray body 62 along the XY-plane (direction substantially parallel to the top surface 611 of the wafer set plate 61) and cause the wafer set plate 61 to smoothly vibrate with respect to the tray body 62. As a specific example of this rolling element 65, for example, a ball or a roller etc. for bearing use may be illustrated. Note that, this ball or roller etc. is equivalent to one example of rolling element in the present invention.

Note that, while not particularly shown, in the present embodiment as well, in the same way as the wafer tray 50 in the first embodiment, the wafer set plate 61 may also have a heater or temperature sensor embedded in it or the wafer set plate 61 may have a cooling passage formed inside it.

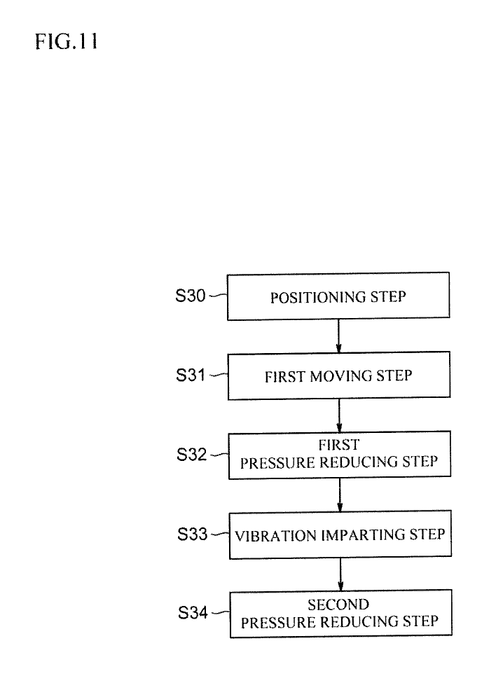

Next, the test method of a semiconductor wafer 100 by a semiconductor wafer test apparatus which comprises the wafer tray 60 explained above will be explained while referring to FIG. 11 to FIG. 12D.

FIG. 11 is a flow chart which shows a test method of a semiconductor wafer in the present embodiment, while FIG. 12A to FIG. 12D are views which show the steps of FIG. 11.

In the same way as the first embodiment, when a semiconductor wafer 100 is placed on a wafer tray 60, the first vacuum pump 55 operates and the semiconductor wafer 100 is held by suction on the wafer tray 60.

Next, using the first and second cameras 46 and 77, the movement apparatus 70 positions the semiconductor wafer 100 with respect to the probe 40 (step S30 of FIG. 11). Then, in step S31 of FIG. 11, as shown in FIG. 12A, the movement apparatus 70 moves the holding stage 75 upward until a position where the wafer tray 60 can stick to the probe 40 by suction.

Next, in step S32 of FIG. 11, as shown in FIG. 12B, the third vacuum pump 76 stops so as to release the suction hold of the wafer tray 50 by the holding stage 75 and the second vacuum pump 56 operates so as to reduce the pressure inside the sealed space to the first pressure P₁. This first pressure P₁ is a pressure of an extent whereby the electrodes 110 of the semiconductor wafer 100 and the bumps 411 of the probe 40 contact by a weak force, for example, 0.1 to 2 [gf/pin] (=0.98×10⁻³ to 19.6×10⁻³ [N/pin]) or so and is a pressure of a low relative vacuum degree.

Note that, instead of steps S31 and S32, it is also possible, like in step S11 of the first embodiment, that the movement apparatus 70 moves the holding stage 75 until a position where the electrodes 110 of the semiconductor wafer 100 and the bumps 40 of the probe 40 contact each other. In this case, the second vacuum pump 56 is not operated while the third vacuum pump 76 is operating, and, after the next step S33 is completed, the third vacuum pump 76 stops.

Next, in step S33 of FIG. 11, as shown in FIG. 12C, the vibration actuator 64 of the wafer tray 60 is driven and the wafer set plate 61 is vibrated with respect to the tray body 62 so as to vibrate the semiconductor wafer 100 with respect to the probe 40. Due to this, the electrodes 110 of the semiconductor wafer 100 are scrubbed by the bumps 411 of the probe 40 and the oxide films which is formed on the surfaces of the electrodes 110 are broken, so stable electrical connection between the probe 40 and the IC devices of the semiconductor wafer 100 can be secured.

Next, in step S34 of FIG. 11, as shown in FIG. 12D, the second vacuum pump 56 is used to reduce the pressure in the sealed space to the second pressure P₂. This second pressure P₂ is a pressure which is lower relative to the above-mentioned first pressure P₁ (P₂<P₁) and a pressure which is high in relative vacuum degree.

Due to this pressure reduction, the wafer tray 60 is further pulled to the probe 40 and the electrodes 110 of the semiconductor wafer 100 are pushed against the bumps 411 of the probe 40 by a strong force of for example 5 to 10 odd [gf/pin] (=49.0×10⁻³ to 200.0×10⁻³ [N/pin]) or so, so the electrodes 110 and the bumps 411 completely connected with each other. In this state, the test head 30 causes test signals to be input through the probe 40 to the IC devices of the semiconductor wafer 100 and output back so as to run tests on the IC device.

In this way, in the present embodiment, a semiconductor wafer 100 is vibrated relative to the probe 40 through the wafer tray 60, so the oxide film which is formed on the electrodes 110 of the semiconductor wafer 100 can be broken and stable electrical connection between the IC devices of the semiconductor wafer 100 and the probe 40 can be secured.

Further, in the present embodiment, the wafer tray 60 itself is provided with a vibration-imparting mechanism, so, for example, when a plurality of the test heads 30 share a single movement apparatus 70, while the wafer tray 60 is being used to impart vibration, the movement apparatus 70 may perform other work (movement or positioning etc. of another semiconductor wafer 100), so the operating rate of the semiconductor wafer test apparatus as a whole can be improved.

The above explained embodiments were described for facilitating understanding of the present invention and were not explained for limiting the present invention. Therefore, the elements which are disclosed in the above embodiments include all design modifications and equivalents which fall under the technical scope of the present invention.

### REFERENCE SIGNS LIST

1 semiconductor wafer test apparatus
30 . . . test head
40 . . . probe
50 . . . wafer tray
   51 . . . seal member
   54 . . . sealed space
   55 . . . first vacuum pump
   56 . . . second vacuum pump
60 . . . wafer tray
   61 . . . wafer set plate
   62 . . . tray body
      622 . . . holding part
      624 . . . suction passage
      626 . . . pressure reduction-use passage
      627 . . . suction hole
   62 . . . first seal member
   63 . . . second seal member
   64 . . . vibration actuator
   65 . . . rolling element
   66 . . . sealed space
70 . . . movement apparatus
100 . . . semiconductor wafer
   110 . . . electrode

1. A wafer tray which holds a semiconductor wafer, comprising:
a set part on which the semiconductor wafer is set;
a main body which supports the set part to be able to finely move; and
a vibration imparting device which imparts vibration to the set part.

2. The wafer tray as set forth in claim 1, wherein
the vibration imparting device is interposed between the set part and the main body.

3. The wafer tray as set forth in claim 1, wherein
the vibration imparting device includes a piezoelectric ceramic actuator.

4. The wafer tray as set forth in claim 1, further comprising
rolling elements which are interposed between the set part and the main body.

5. A semiconductor wafer test apparatus comprising:
a wafer tray as set forth in claim 1;
a moving device which moves the wafer tray relative to a probe which is to be electrically connected to devices under test which are formed on the semiconductor wafer; and
a pressure reducing device which reduces a pressure of a sealed space which is formed between the probe and the wafer tray.

6. A test method of a semiconductor wafer using a semiconductor wafer test apparatus as set forth in claim 5, the test method by comprising:
using the moving device to move the wafer tray so as to form a sealed space between the probe and the wafer tray;
using the pressure reducing device to reduce a pressure of the sealed space to a first pressure;
using the vibration imparting device to vibrate the wafer tray in a state where electrodes of the semiconductor wafer and contactors of the probe contact; and
using the pressure reducing device to reduce a pressure of the sealed space to a second pressure which is lower than the first pressure.

7. A semiconductor wafer test apparatus comprising:
a wafer tray which holds a semiconductor wafer;
a moving device which moves the wafer tray relative to a probe which is to be electrically connected to devices under test which are formed on the semiconductor wafer;
a pressure reducing device which reduces a pressure of a sealed space which is formed between the probe and the wafer tray; and
a vibration imparting device which imparts vibration to the wafer tray.

8. A test method of a semiconductor wafer using a semiconductor wafer test apparatus as set forth in claim 7, the test method comprising:
using the moving device to move the wafer tray relative to the probe so that electrodes of the semiconductor wafer and contactors of the probe contact;
using the vibration imparting device to vibrate the wafer tray in a state where the electrodes and the contactors contact; and
using the pressure reducing device to reduce a pressure of the sealed space.

9. The test method of a semiconductor wafer using a semiconductor wafer test apparatus as set forth in claim 7, the test method comprising:
using the moving device to move the wafer tray so as to form a sealed space between the probe and the wafer tray;
using the pressure reducing device to reduce a pressure of the sealed space to a first pressure;
moving the moving device so that the moving device again contacts the wafer tray;
using the vibration imparting device to vibrate the wafer tray in a state where electrodes of the semiconductor wafer and contactors of the probe contact; and
using the pressure reducing device to reduce a pressure of the sealed space to a second pressure which is lower than the first pressure.

10. The test method of a semiconductor wafer using a semiconductor wafer test apparatus as set forth in claim 7, the test method comprising:
using the moving device to move the wafer tray so as to form a sealed space between the probe and the wafer tray;
using the pressure reducing device to reduce a pressure of the sealed space to a first pressure;
using the vibration imparting device to vibrate the wafer tray in a state where electrodes of the semiconductor wafer and contactors of the probe contact; and
using the pressure reducing device to reduce a pressure of the sealed space to a second pressure which is lower than the first pressure.
